(19) United States
(12) Patent Application Publication
(10) Pub. No.: US 2018/0151482 A1
(43) Pub. Date: May 31, 2018

(54) ELECTRONIC DEVICE, MANUFACTURING METHOD AND LEAD FRAME FOR SAME

(71) Applicant: NEXPERIA B.V., Eindhoven (NL)

(72) Inventors: WAI HUNG HOR, Kwai Chung (HK); Ke Xue, Kwai Chung (HK); Chi Ho Leung, Kwai Chung (HK); Yee Wai Fung, Kwai Chung (HK)

(21) Appl. No.: 15/345,478

(22) Filed: Nov. 7, 2016

(30) Foreign Application Priority Data
Dec. 1, 2015 (CN) 201510867964.0

(51) Int. Cl. H01L 23/495; H01L 23/31; H01L 21/56

(52) U.S. Cl. CPC H01L 23/49565; H01L 21/561; H01L 23/3107

(57) ABSTRACT

An electronic device has a first surface providing electrical contact points and multiple side surfaces surrounding the first surface. The electronic device includes a lead frame and a device die attached to the lead frame. The lead frame is located at a side of the first surface of the electronic device, and is configured to provide solder pads on the first surface of the electronic device. A lead frame for the electronic device and a method for assembling the electronic device also are provided.

### BACKGROUND

The present invention generally relates to an electronic device and a manufacturing method therefor, as well as a lead frame for the electronic device. More particularly, the present invention relates to side-solderable electronic device, a manufacturing method therefor, and a lead frame for providing the side-solderability of the electronic device.

Various Small Outline Package (SOP) electronic device structures, for example SON (Small Outline Package, No leads), QFN (Quad Flat No-lead), and DFN (Dual Flat-Pack No-lead) have been developed to meet component miniaturization demands of the electronics industry. With respect to packages with leads, these package forms have better electrical performance, are smaller and thinner, and have improved thermal dissipation.

After the electronic devices are assembled, they are attached to corresponding external circuit systems for operating in accordance with their designed functions. Typically, the electronic devices are connected to printed circuit boards (PCB) through solder techniques. The solder joint reliability greatly impacts the fulfillment of the device's function. Automatic Optical Inspection (AOI) typically is used to check the PCB after solder to determine, through profiles of the electronic devices after solder, if there's rosin joint, tilt, or missing solder.

For general leadless packaging, the solder pads of the electronic device are located on the surface of the device facing the PCB. After solder, the welding spots are sandwiched between the PCB and the electronic device and therefore are not readily visible. When using AOI machines to inspect the solder joints, the solder features of such general leadless packages cannot be captured for further determination of solder reliability.

A better detection method for leadless packages is to use AXI (Automatic X-ray Inspection). As known, the equipment and processes for AXI inevitably add to the manufacturing and inspection cost.

Along with the need for continual improvement of integration level and optimization of electrical performance, there also are requirements for further miniaturization and addressing dissipation issues.

### SUMMARY

This summary is provided to introduce a selection of concepts in a simplified form that are further described below in the Detailed Description. This summary is not intended to identify key or essential features of the claimed subject matter, nor is it intended to be used to limit the scope of the claimed subject matter.

A lead frame includes an array of multiple lead frame assemblies; wherein each lead frame assembly includes:
on a side thereof at a first direction, at least one terminal; and
on at least one side at a second direction of the at least one terminal, a connection bar; wherein
the second direction intersects the first direction;
the connection bar extends along the first direction to a neighboring lead frame assembly; and
the connection bar and the terminal surround a first space between neighboring lead frame assemblies.

An electronic device has a first surface providing electrical contact points and multiple side surfaces surrounding the first surface. The electronic device includes a lead frame and a device die attached on the lead frame; the lead frame is located in a side of the first surface of the electronic device, and the lead frame is configured to provide solder pads on the first surface for the electronic device.

A method for manufacturing an electronic device includes:
providing a lead frame;
providing a device die;
attaching the device die to the lead frame;
encapsulating the device die and the lead frame using molding material into a molded body; wherein the molding material fills in the first space, and the terminal exposes on a first surface of the molded body;
ablating, along a direction perpendicular to the first surface, in a space of the molded body between the terminal and a neighboring lead frame assembly thereof until the molded body is penetrates, so that a side at the first direction of the terminal is exposed;
applying plating layers on the exposed side at the first direction and a part exposed on the first surface of the terminal;
sawing, along the second direction perpendicular to the first direction and out of the terminal, the molded body so that the molding material between neighboring lead frame assemblies are removed.

Accordingly, the manufactured electronic device with the lead frame can have the solder joint with the PCB at the side thereof, which is easy to go through AOI inspection. The structure of side connection between the electronic device and the PCB has advanced electrical performance and thermal dissipation, and the reliability of the electronic device is improved.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments. The drawings are for facilitating an understanding of the invention and thus are not necessarily drawn to scale. Advantages of the subject matter claimed will become apparent to those skilled in the art upon reading this description in conjunction with the accompanying drawings, in which like reference numerals have been used to designate like elements, and in which:

FIG. 1 is a perspective view of an electronic device according to an embodiment of the present invention;

FIGS. 2A-2D are cross-sectional views of parts of structures formed in steps of a method of assembling the electronic device of FIG. 1, in accordance with an embodiment of the present invention;

FIG. 3 is a side view of a an electronic device in accordance with an embodiment of the present invention attached to a PCB;

FIG. 4 is a cross-sectional view of part of a lead frame with recesses during assembly of an electronic device in accordance with an embodiment of the present invention;

FIG. 5 is a photograph of a portion of an electronic device assembled using a lead frame having recesses at its side, in accordance with an embodiment of the present invention;

FIG. 6 is a cross-sectional view of an electronic device during singulation in accordance with an embodiment of the present invention;

FIGS. 7A and 7B are enlarged, planar views of a lead frame in accordance with an embodiment of the present invention;

FIGS. 8A-8I are illustrative views of structures in a method of assembling an electronic device in accordance with an embodiment of the present invention; and

FIG. 9 is a perspective view of an electronic device in accordance with an embodiment of the present invention.

### DETAILED DESCRIPTION

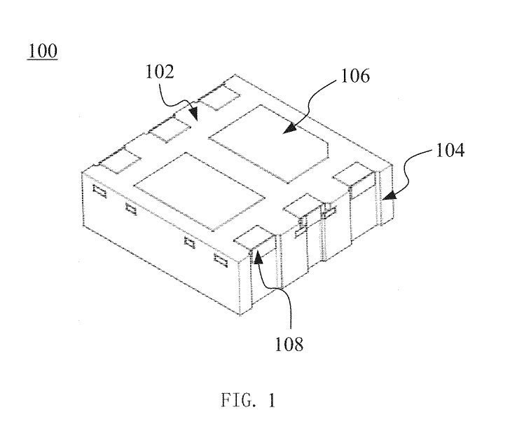

Referring to FIG. 1, a perspective view of an electronic device 100 according to an embodiment of the present invention is shown. The electronic device 100 has a first surface 102 and multiple side surfaces 104. Contact points 106 are provided on the first surface 102 for the electronic device 100 to be connected externally. The multiple side surfaces 104 surround the first surface 102, and optionally are perpendicular to the first surface 102.

For providing the external connections for the electronic device 100, multiple contact points/solder pads 106, 108 are disposed on the first surface 102. In optional embodiments, the contact points/solder pads 106 and 108 are provided by a lead frame included in the electronic device 100. An example material for the lead frame is copper (Cu). For the lead frame to provide the contact points/solder pads, the lead frame is preferably located at a side of the electronic device 100 near the first surface 102. The electronic device 100 normally includes a lead frame and a device die. After the device die is attached to the lead frame, the combined structure is molded using molding materials. Exposed parts of the lead frame that are electrically connected to corresponding parts of the device die provide external connections for the electronic device. When the electronic device 100 is attached to a PCB (Printed Circuit Board) through technologies like SMT (Surface Mounting Technology), solder usually is used to connect the electronic device 100 to the PCB, such that the exposed parts of the lead frame are provided as solder pads for the attachment.

Besides the solder pads 106 on the central position of the first surface 102 of the electronic device 100, there also are solder pads 108 located at positions where the first surface 102 abuts the side surfaces 104. As shown in FIG. 1, the solder pads 108 extend from the first surface 102 onto the side surface 104, and extend at least partially along the side surface 104. In alternative embodiments, the solder pads 108 extend along the side surface 104 for a distance that is equal to a thickness of the lead frame of the electronic device 100. It will be understood by those if skill in the art that, after the lead frame is molded in the molding material, the lead frame is exposed both on the first surface 102 and on the side surface of the electronic device 100, such that part of the lead frame at positions where the first surface 102 abuts the side surfaces 104 can extend both on the first surface 102 and on the side surface 104, and that the extending distance along the side surface 104 is equal to the thickness of the lead frame.

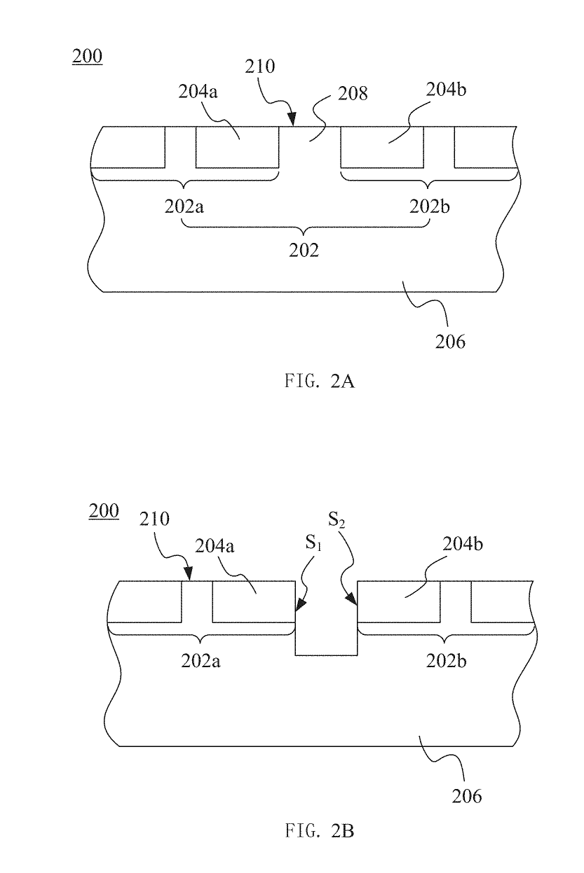

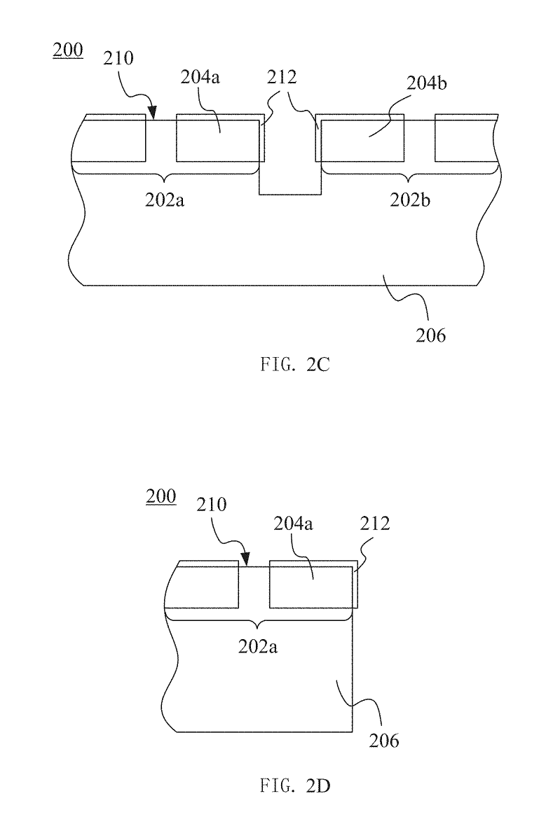

FIGS. 2A-2D are side views of structures formed in steps of a method for assembling the electronic device of FIG. 1 in accordance with an embodiment of the present invention.

First, a lead frame 202 and a device die (not shown) are provided. As shown in FIG. 2A, the lead frame 202 is provided as an array of lead frame assemblies 202a and 202b. In FIG. 2A, only the lead frame assemblies along an X-direction are shown. However, it will be understood by those if skill in the art that, in a Y-direction perpendicular to the X-direction, the lead frame 202 includes multiple lead frame assemblies. The lead frame 202 includes terminals 204a and 204b on sides of each of the lead frame assemblies 202a and 202b facing each other. In the lead frame 202, there is a space 208 between a side of the terminal 204a of the lead frame assembly 202a and the facing lead frame assembly 202b.

Next the device die is attached to the lead frame 202, and the assembled device die and lead frame 202 are molded using molding material 206 to form a molded body 200. The molding material 206 fills the space 208 between the terminals 204a and 204b, with the terminals 204a and 204b exposed at a first surface 210 of the molded body 200. The structure of the assembly is illustrated in FIG. 2A.

Referring to FIG. 2B, the molded body 200 shown in FIG. 2A is cut. Starting at the space 208 between the terminals 204a and 204b, the molded body 200 is cut along a direction of its thickness until at least the thickness of the lead frame 202 is exceeded. Facing sides S1 and S2 of the terminals 204a, 204b are exposed after the cut. It will be understood by those of skill in the art that the cut can be performed using mechanical, chemical or laser methods so as to ablate. In other embodiment, the molded body 200 can be cut along a direction of its thickness until the molded body 200 is totally penetrated. In one embodiment, when using laser ablation, a power of the laser can be 30 W.

After cutting, a plating layer 212 is applied on parts of the terminals 204a and 204b that are exposed on the first surface 210 of the molded body 200, and on the sides S1 and S2. In FIG. 2C, for ease of display, the plating layer 212 is exaggerated. It will be understood that, in the plating process, surfaces of the parts of the lead frame assemblies 202a and 202b exposed at the first surface 210 other than the terminals 204a and 204b are plated with corresponding layers. The plating process may comprise electroplating or any other ways for forming plating. One material used for the plating is NiPdAu.

Finally, removing molding materials 206 between the lead frame assemblies 202a and 202b such that electronic devices are singulated, with terminal 204 of the lead frame 202 exposed respectively on the first surface 210 and the side Si, and have plating layers covered thereon. Referring to FIG. 2D, the obtained electronic device can be in the form of that illustrated in FIG. 1.

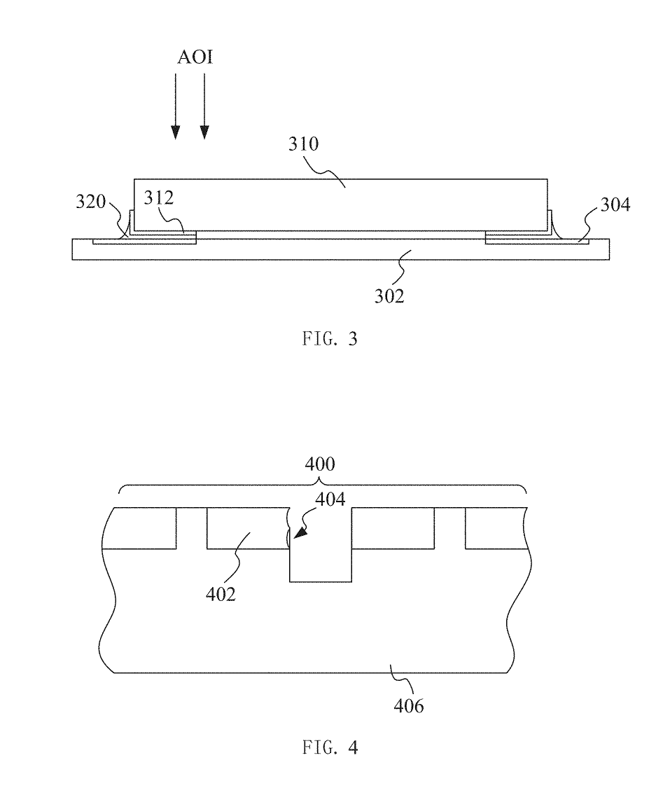

Turning to FIG. 3, a sectional view of a joint structure of the electronic device of FIGS. 1 and 2 being assembled onto the PCB and having a solder structure with solder points of the PCB is shown.

The PCB includes a substrate 302 and solder points 304 on the substrate. It will be appreciated that the substrate 302 is made of organic insulating material, the solder points 304 are electrical connection structures like traces or pads that are formed on the substrate 302 through electroplating or etching, etc. In assembling an electronic device 310, according to an embodiment of the present invention, on the PCB through technologies like SMT, a first surface thereof faces the PCB, with exposed parts of its terminals 312 on the first surface being aligned with the solder points 304 on the PCB. Optionally, solder can be disposed on the solder points 304 of the PCB using stencil printing, etc. As the electronic device 310 is placed thereon, the solder contacts the terminals 312 on the first surface of the electronic device 310. Further, the solder is disposed on parts of the solder points 304 out from lateral dimensions of the electronic device 310. In a following heat welding process, the solder is heated to melt so that the terminals 312 and corresponding solder points 304 of the PCB are connected. At the same time, the solder outside of the lateral dimensions of the electronic device 310 melts and creeps onto sides of the terminals 312 due to surface tension, thereby a sloped contact on sides of the electronic device 310 is obtained. In the end, solder under the terminals 312 and on the side of the terminals 312 jointly composes the electrical connection 320 between the electronic device 310 and the PCB.

When inspecting the connection between the electronic device 310 and the PCB, the sloped solder on side of the terminals 312 of the electronic device 310 can captured and inspected, and accordingly used as a basis for evaluating the connection. Besides the conventional face to face connection, the electronic device of the present embodiment provides additional side connections of electrical and mechanical type, which enhances reliability of the connection between the electronic device and the PCB, while tilt and warpage can be eliminated.

In FIG. 3, dimensions of the terminals 312 are enlarged to illustrate the plating applied thereon, and the electrical connection 320 also is enlarged for ease of understanding.

Lead frames are normally manufactured through stamping, etching, etc. Referring to FIG. 4, a lead frame 400 is manufactured using etching such that recesses 404 are formed on sides of terminals 402 of the lead frame 400 by the etching process itself, such as over-etching. If the method of the embodiment illustrated in FIGS. 2A-2D is used for assembling electronic devices using lead frames with recesses, there will be molding material 406 left in the recesses 404 so that subsequent application of plating material onto sides of the terminals 402 will be affected. Parts of the sides of the terminals 402 covered by the molding material 406 are covered with the plating material, so when the electronic device is attached on the PCB, the above-described side connection/solder is limited, which in turn affects the electrical and mechanical connection between the electronic device and the PCB, and affects the detectability using AOI instruments. FIG. 4 illustratively shows a recess in the left terminal. It should be understood that the terminal on the right can have the same or similar recesses.

FIG. 5 shows a section of an electronic device with a lead frame having recesses on the side. It can be seen from FIG. 5 that at least part of the side of the terminal of the lead frame is not effectively covered by the plating layer due to residuary molding material. It is conceivable that, when the electronic device of FIG. 5 is attached to a PCB, there can even be no electrical connection on the side.

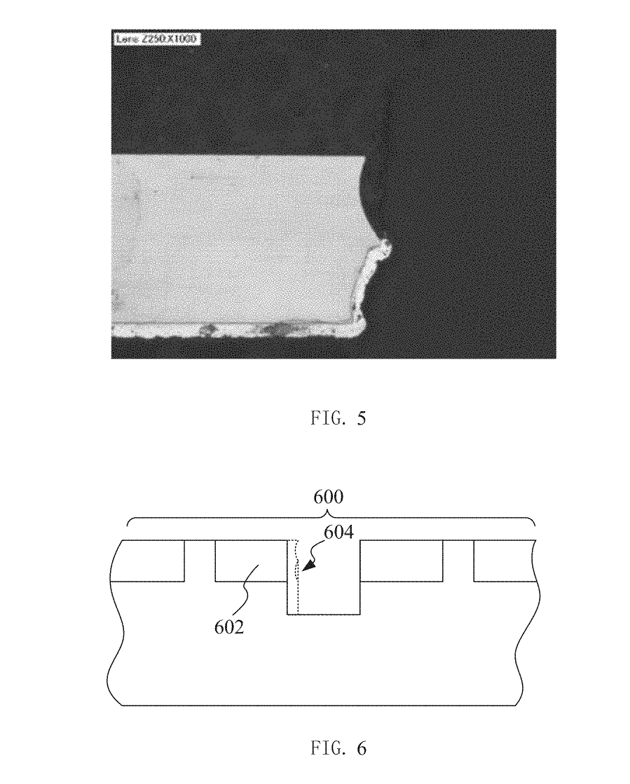

Accordingly, a further embodiment provides a method for assembling an electronic device. The method is similar to the embodiment shown in FIGS. 2A-2D. However, a difference is shown in FIG. 6. According to the embodiment shown in FIG. 6, when cutting the molded body like the step in FIG. 2B, besides removing the molding material in spaces near sides of the terminals 602 of the lead frame 600, a width of the cut is expanded to an extent that the recesses 604 (shown in dashed lines) are removed. The expansion of the cutting width is at least equal to a depth of the recesses 604. According to an optional embodiment, the cutting width is expanded by 40 μm to 50 μm. By use of the expanded cutting, the side of the terminal 602 along the total thickness of the lead frame 600 is exposed, while the recesses 604 and the residuary molding material therein are removed so that the side of the terminal is conformal. Due to the removal of the molding material through the expanded cutting, there is no obstacle on sides of the terminals 602 to impede the application or attaching of a plating layer. The electronic device is further advantageous in the assembly with PCB, having enhanced detectability of the electrical and mechanical connection. Similar to the illustration in FIG. 4, FIG. 6 only shows an example on the left part in FIG. 6. In other embodiments, the terminal on the right could have the same or similar recesses and can be removed through expanded cutting.

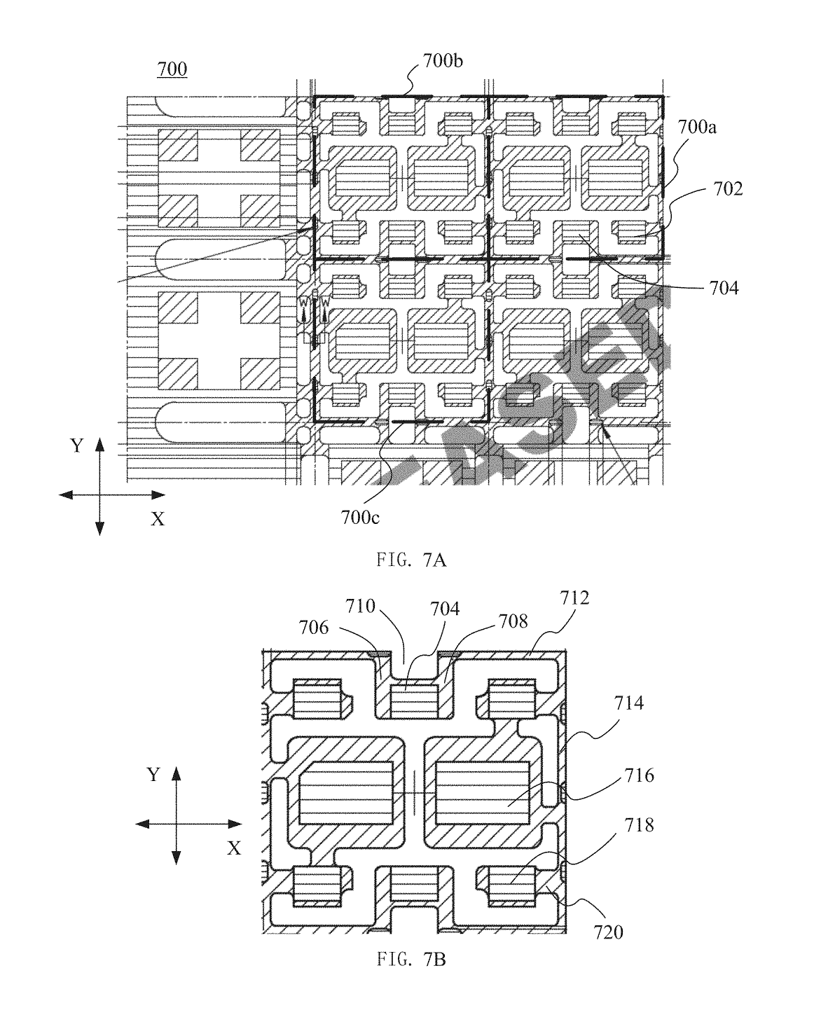

FIGS. 7A and 7B are top plan views of part of a lead frame for assembling electronic devices according to an embodiment of the present invention.

The lead frame 700 includes an array of lead frame assemblies 700a, 700b, and 700c. The lead frame assembly 700a includes terminals 702, 704, etc. on a side thereof facing a neighboring lead frame assembly along a Y-direction. It should be understood that each of the lead frame assemblies in FIG. 7 is used for assembling an individual electronic device, where a device die is placed on the lead frame assembly, and terminals 702, 704 are connected to the device die using wire bonding or flip-chip, etc. The terminals 702, 702 are electrically connected to the device die, and provide external signal communications for the device die.

FIG. 7B is an enlarged view of a lead frame assembly in the lead frame of FIG. 7A. The lead frame assembly includes connection bars 706 and 708 on both sides in an X-direction of the terminal 704. Referring to FIGS. 7A and 7B, the connection bars 706 and 708 extend along a Y-direction until sides in the X direction of the terminal of a neighboring lead frame assembly. Because the connection bars 706 and 708 are attached to both sides in the X-direction of the terminal 704, and extend along the Y-direction to a neighboring lead frame assembly, there is a space 710 surrounded by the terminal 704, and the connection bars 706 and 708, between the terminal 704 and the terminal of the neighboring lead frame assembly connected with the same connection bars.

Optionally, in an exemplary embodiment, the space can be included the connection bar only on one side of the terminal at its side in the X-direction. The connection bars 706 and 708 are configured such that the terminal 704 is substantially perpendicular to the connection bars.

Further, the lead frame includes support bars 712 between neighboring lead frame assemblies. In one embodiment, the support bars 712 are connected to a midpoint of the connection bars that connect neighboring lead frame assemblies. The support bars 712 extend in the X-direction to a length equal to a length of the lead frame assembly in the X-direction. In other words, the support bars 712 extend in the X-direction to a length between sides of the lead frame assembly.

The lead frame further includes second support bars 714 that extend in the Y-direction between the lead frame assemblies. The second support bars 714 are connected to at least a part of the lead frame assembly, such as a die bonding pad 716. The second support bars 714 extend in the Y-direction and optionally connect to the support bars 712 at a corner of the lead frame assembly.

Referring to FIG. 7B, the lead frame assembly further includes a second terminal 718 on a Y-directional side. For clear illustration, the embodiment shown in FIG. 7B labels the second terminal 718 on the side symmetrical to the terminal 704 side. It can be seen that, in the current embodiment implemented as symmetrical structure, similar second terminals (not labelled) are included at the same side of the terminal 704. In optional embodiments, the second terminals 718 are disposed at a side of the lead frame assembly and in a linear alignment with the terminal 704. In the embodiment shown in FIG. 7B, two second terminals 718 are included on each X-direction side of the terminal 704. In other optional embodiments, more or fewer second terminals 718 can be included.

A second connection bar 720 is connected to an X-direction side of the second terminal 718. The second connection bar 720 extends along the X-direction until it connects to the second support bar 714, such that the second connection bar 720 connects to an X-direction side of the second support bar 714. The second terminal 718 is mechanically supported by the second support bar 714 through the second connection bar 720, such that the second terminal 718 is physically separate from the terminal 704.

Still with reference to FIGS. 7A and 7B, intersecting support bars 712 and second support bars 714 connect to the terminals 704, 718 and bonding pad 716 through the connection bars 706, 708 and 720 to provide mechanical support for these parts that need to be connected to the device die.

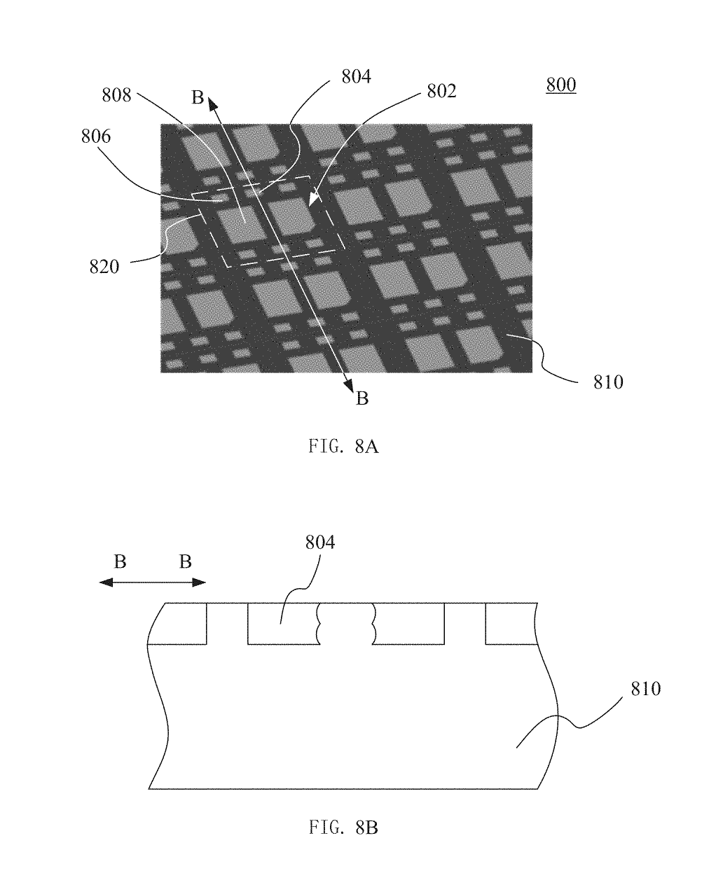

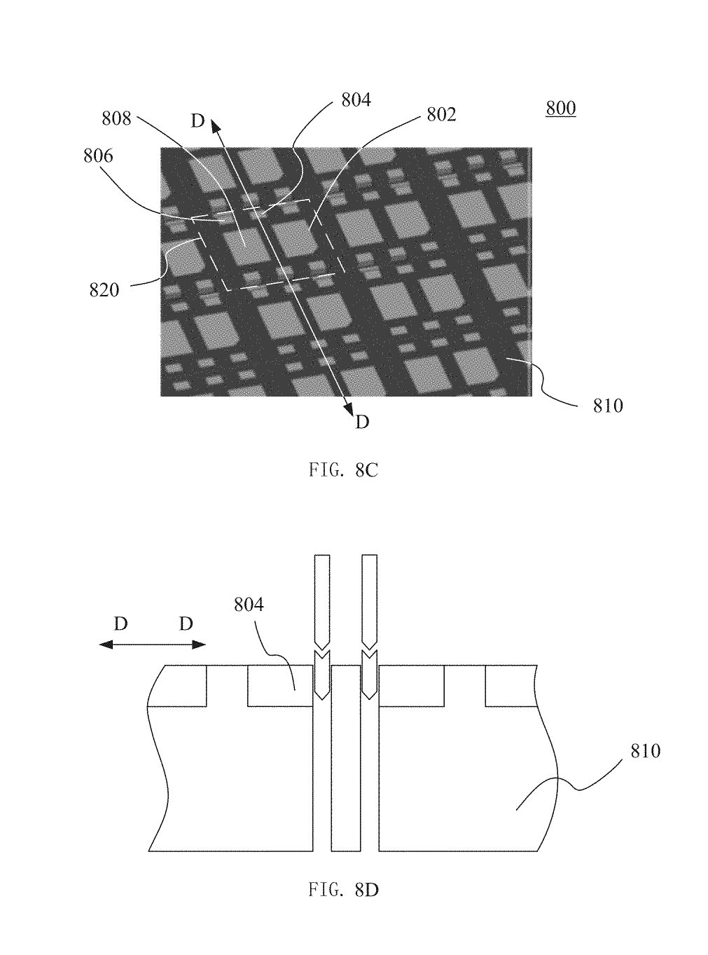

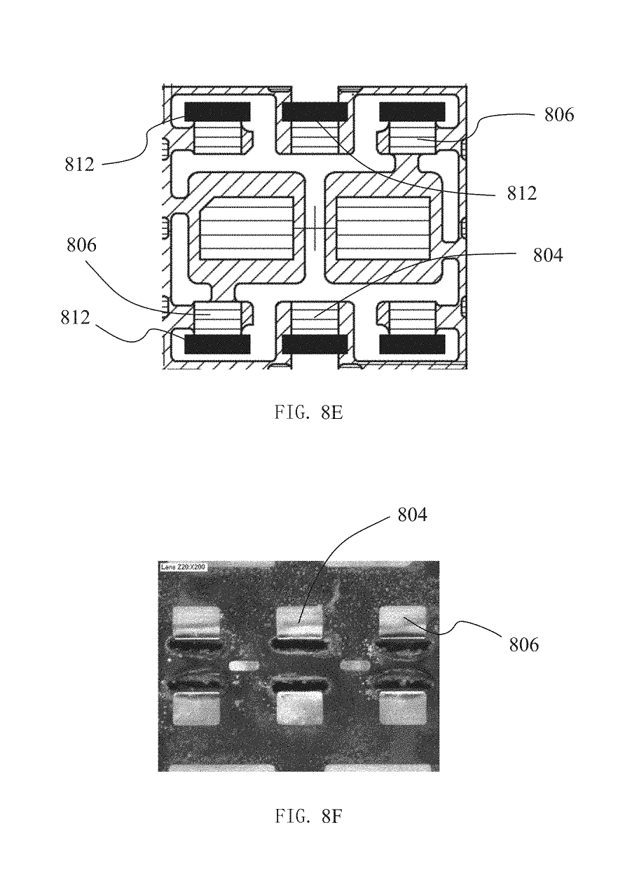

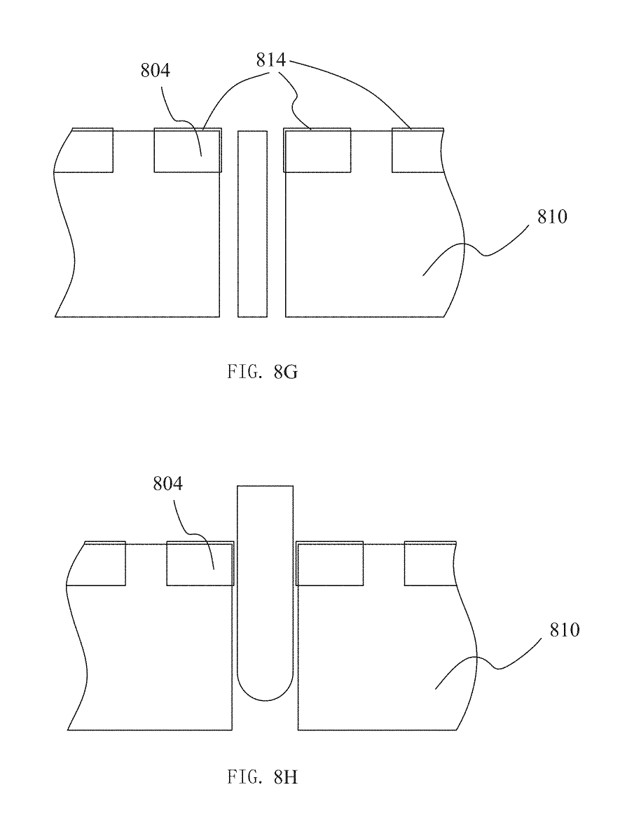

Referring to FIGS. 8A-8I, schematic diagrams illustrating corresponding structures in steps of assembling an electronic device according to an embodiment of the present invention are shown. In the current embodiment, the lead frame used for assembling the electronic device can be the implementation of the lead frame of FIGS. 7A and 7B.

FIGS. 8A and 8B are respectively a perspective surface view and a sectional view along line B-B of a structure obtained through molding an assembly of lead frames and attached device dies using molding material, after attaching the device die to the lead frame. In FIG. 8A, in a molded body 800 using molding material 810, each lead frame assembly and the corresponding attached device die will form a separate electronic device 820. Before singulation, the electronic devices 820 are connected with each other by the molding material 810 and the buried connection bars and support bars of the lead frame. On a surface 802 of each electronic device 820, terminals 804, second terminals 806 and die bonding pads 808 are exposed.

Referring now to FIG. 8B, being similar to the above mentioned FIGS. 4 and 5, the lead frame of the electronic device 820 includes the terminals 804 with recesses formed by over etching in manufacturing procedures of the lead frame, and the recesses are filled with molding material 810.

Further referring to FIGS. 8C and 8D, which respectively shows a perspective surface view and a sectional view along line D-D of the molded body 800 of FIG. 8A in following steps. In the current step, the molded body is ablated, along a thickness direction thereof, in spaces between a terminal 804 of one electronic device 820 and the terminal 804 of a neighboring electronic device 820. Filled molding material in the space between neighboring terminals 804 of neighboring electronic devices is removed through the ablation, which exposes sides of the terminals 804.

Preferably, recesses and the molding material filled therein as shown in FIG. 8B are removed through the ablation. For the removal of such recesses and filled molding material, the ablation width is expanded to an extent that at least a part of the side of the terminal 804 facing the neighboring electronic device is removed. In an optional embodiment, the ablation is implemented as laser ablation with a power selected as 70 W. Through the use of the higher laser power, the ablation width can be expanded by approximately 40 μm-50 μm. Optionally, the ablation reaches a depth that penetrates the thickness of the molded body 800, so that through holes are drilled through on the side of the terminals 804 of the molded body 800. Through the ablation to the extent of penetrating the thickness of the molded body 800, the side of the terminal 804 and the side of the beneath molding material 810 exposed are coplanar.

Further referring to FIG. 8E, positions 812 are the position where ablation to the molded body 800 is performed. It can be seen that besides the ablation on the side of the terminal 804, the side of the second terminal 806 is also ablated. A surface view of part of the molded body 800 after the ablation is shown in FIG. 8F. Corresponding through holes can be seen beside the terminals 804 and the second terminals 806.

Referring further to FIG. 8G, similar to the step described with reference to FIG. 2C, plating layers are applied to bottom and side surfaces of the exposed terminals 804 and second terminals 806. Parts of the terminals 804 and the second terminals 806 that exposed from the molding material 810 are covered with the plating layer 814 after this step. In FIG. 8G, for convenient illustration, the sizes of the plating layers are enlarged. As described above, the ablation shown in FIG. 8D penetrates the molded body 800. When the exposed terminals 804 and second terminals 806 are electroplated using plating solutions, the through holes benefit from the influx of plating solutions such that the sides of the terminals 804 and second terminals 806 are covered with the plating layers.

Subsequently, referring to FIG. 8H, the molded body 800 is sawn between the electronic devices 820 so that the molding material 810 and the connection bars, support bars buried therein between neighboring electronic devices 820 are removed, thereby singulation is performed to separate electronic devices 820. Specifically, the singulation includes sawing the molded body 800 along perpendicular directions. It will be understood that at the side of the electronic device 820 with the terminals, since the above-described ablation only penetrates the molded body 800 in a range of about the length of the terminals 804, there's still unremoved molding material on sides of the neighboring electronic devices 820 between the relative terminals and on perpendicular sides thereof. The unremoved molding material connects the neighboring electronic devices.

FIG. 8I illustrates an example of the saw singulation. In FIG. 8I, lines 816 depicts a range of singulation sawing between neighboring electronic devices 820. Optionally, the singulation sawing does not strictly align with or is not coplanar a plane of the sides of the terminals 804 and second terminals 806 exposed after the above-described ablation. Alternatively, the singulation sawing is a little retreated with respect to the sides of the terminals 804. After singulation, the molding material 810 that filled the space between relative terminals of neighboring electronic devices is removed. Further, after the singulation, an exposed side of a part 818 of the electronic device 820 between neighboring terminals, such as the terminal 804 and the second terminal 806, is parallel with the sides of the terminals after the ablation instead of being coplanar due to the retreated singulation. It will be appreciated that the singulation sawing can be coplanar with the side of the terminals 804, which will result in a coplanar side of the electronic device between the exposed side of the part 818 and the exposed side of the terminals 804 and second terminals 806.

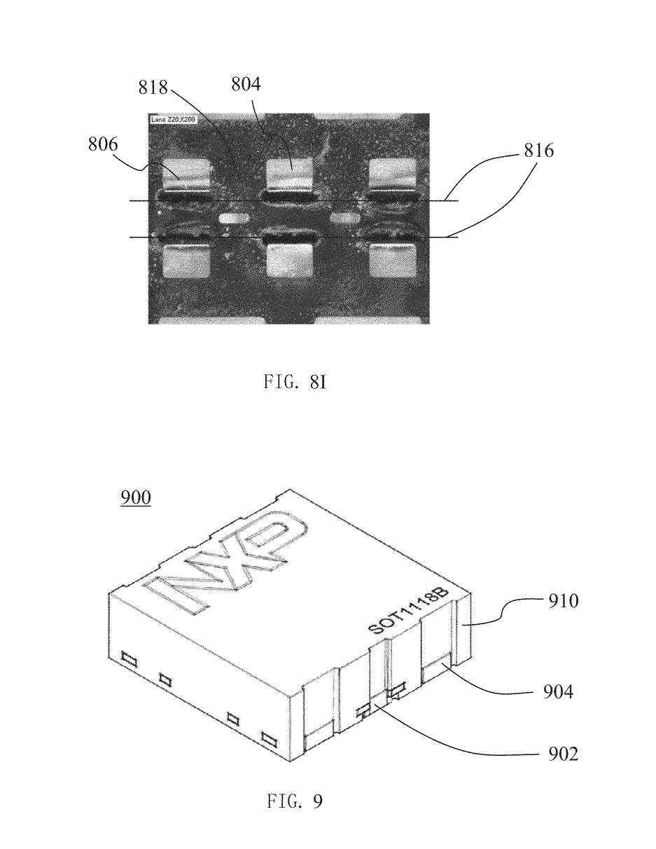

Referring to FIG. 9, after the steps of assembling the electronic device, in an electronic device 900, sides of terminal 902 and 904 and the part of the above molding material 910 are coplanar through the ablation method. However, the side of part of the molding material 910 between the terminals 902 and 904 are slightly protruded such that the sides of the terminals 902 and 904 are relatively recessed. The slightly recessed space is obtained through the above-described ablation and singulation of the filled molding material 910 between relative terminals of neighboring lead frame assemblies of the lead frame. As the electronic device 900 is attached to a PCB, the terminal 902 in the recessed space is connected with solder through contacting the melted solders. While on the other hand, the molding material 910 on both sides of the terminal 902 act as a reservoir bar for the melted solder to prevent the solder from spreading to parts other than the terminal 902, which would pollute or have a negative impact on the solder joint. Thereby, the recessed space obtained through the ablation and sawing can be used for improving the solderability of the electronic device 900, and enhance the solder joint. Further, since the sides of the terminals 902, 904 are coplanar with the sides of the molding material 910 above the terminals 902 and 904 through the above-mentioned ablation step, the recessed space will affect the detection through AOI equipment after solder.

It shall be appreciated that the electronic device 900 not only enables solderability on its side such that AOI equipment can be used to detect the solder joints, but also eliminates the recesses in the side of the lead frame such that metal coatings can be better deposited on the sides of the electronic device 900 to benefit the solder joints with the PCB.

The use of the terms “a” and “an” and “the” and similar referents in the context of describing the subject matter (particularly in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. Furthermore, the foregoing description is for the purpose of illustration only, and not for the purpose of limitation, as the scope of protection sought is defined by the claims as set forth hereinafter together with any equivalents thereof entitled to. The use of any and all examples, or exemplary language (e.g., “such as”) provided herein, is intended merely to better illustrate the subject matter and does not pose a limitation on the scope of the subject matter unless otherwise claimed. The use of the term “based on” and other like phrases indicating a condition for bringing about a result, both in the claims and in the written description, is not intended to foreclose any other conditions that bring about that result. No language in the specification should be construed as indicating any non-claimed element as essential to the practice of the invention as claimed.

Preferred embodiments are described herein, including the best mode known to the inventor for carrying out the claimed subject matter. Of course, variations of those preferred embodiments will become apparent to those of ordinary skill in the art upon reading the foregoing description. The inventor expects skilled artisans to employ such variations as appropriate, and the inventor intends for the claimed subject matter to be practiced otherwise than as specifically described herein. Accordingly, this claimed subject matter includes all modifications and equivalents of the subject matter recited in the claims appended hereto as permitted by applicable law. Moreover, any combination of the above-described elements in all possible variations thereof is encompassed unless otherwise indicated herein or otherwise clearly contradicted by context.

1. A lead frame comprising an array of multiple lead frame assemblies, wherein each lead frame assembly comprises:
on a side thereof in a first direction, at least one terminal; and
on at least one side in a second direction of the at least one terminal, a connection bar, wherein
the second direction intersects the first direction,
the connection bar extends along the first direction to a neighboring lead frame assembly, and
the connection bar and the terminal surround a first space between neighboring lead frame assemblies.

2. The lead frame of claim 1, wherein the first direction is perpendicular to the second direction.

3. The lead frame of claim 1, wherein each lead frame assembly includes connection bars on each side in the second direction of the terminal, wherein the connection bars extend along the first direction to neighboring lead frame assemblies.

4. The lead frame of claim 1, further comprising a support bar connected to the connection bar between neighboring lead frame assemblies, wherein the support bar extends along the second direction to at least a distance of an edge at the second direction of the lead frame assembly.

5. The lead frame of claim 1, further comprising a second support bar mechanically connected between the lead frame assembly and a neighboring lead frame assembly at the second direction, wherein the second support bar extends along the first direction and is at least partly connected to the lead frame assembly.

6. The lead frame of claim 5, further comprising a second connection bar at a side of the second support bar and extending along the second direction, wherein the lead frame assembly further comprises at least one second terminal at a side at the first direction, wherein the second connection bar connects and mechanically supports the second terminal of the lead frame assembly, such that the second terminal and a neighboring terminal at the first direction are physically separated.

7. An electronic device having a first surface and multiple side surfaces surrounding the first surface, the electronic device comprising:
a lead frame assembly comprising solder pads on a first side thereof that extend in a first direction;
a device die attached on and electrically connected to the solder pads of the lead frame assembly; and
molding material that encapsulates the lead frame assembly and the device die, wherein the solder pads are exposed on the first surface and at least one of the multiple side surfaces of the electronic device, wherein the exposed solder pads on the at least one side surface are coplanar with a side of part of the molding material.

8. The electronic device of claim 7, wherein at least one of the solder pads extends on at least one of the multiple side surfaces to a distance of a thickness of the lead frame assembly.

9. (canceled)

10. (canceled)

11. (canceled)

12. The electronic device of claim 7, wherein the side of the electronic device further comprises parts having no side of the lead frame exposed but with sides of the molding material.

13. The electronic device of claim 12, wherein the parts of the side of the electronic device having no side of the lead frame exposed are parallel but not coplanar with the part having the side of the lead frame exposed.

14. A method of assembling an electronic device, comprising:
providing a lead frame, wherein the lead frame comprises an array of multiple lead frame assemblies, wherein each lead frame assembly comprises:
at least one terminal on a side thereof that extends in a first direction; and
a connection bar located on at least one side and that extends in a second direction perpendicular to the first direction, wherein
the connection bar intersects the at least one terminal,
the connection bar extends along the first direction to a neighboring lead frame assembly, and
the connection bar and the terminal define a first space between neighboring lead frame assemblies;
providing a device die;
attaching the device die to the lead frame;
encapsulating the device die and the lead frame using molding material thereby forming a molded body, wherein the molding material fills in the first space, and the terminal is exposed on a first surface of the molded body;
ablating, along a direction perpendicular to the first surface, in a space of the molded body between the terminal and a neighboring lead frame assembly thereof, until the molded body is penetrated, so that a side at the first direction of the terminal is exposed;
applying plating layers on the exposed side at the first direction and an exposed part on the first surface of the terminal;
sawing, along the second direction perpendicular to the first direction and out of the terminal, the molded body so that the molding material between neighboring lead frame assemblies is removed.

15. The method of claim 14, wherein the ablation removes the molding material in the first space, and removes at least a part of a side of the terminal that faces the neighboring lead frame assembly, so that the side at the first direction of the terminal is exposed.

16. The method of claim 14, wherein the ablation exposes an entire side at the first direction of the terminal along the lead frame.

17. The method of claim 14, wherein the ablation is laser ablation.

18. The method of claim 14, wherein the ablation exposes the side at the first direction of the terminal and a side of the molding material covering above the terminal to be coplanar.

19. The method of claim 14, wherein an exposed side at the first direction of the molding material due to the sawing is parallel but not coplanar with the side at the first direction of the terminal due to the ablation.

20. The method of claim 14, wherein the side at the first direction of the terminal due to the ablation is retreated than an exposed side at the first direction of the molding material due to the sawing.
